(19) United States
(12) Patent Application Publication
(10) Pub. No.: US 2013/0141662 A1
(43) Pub. Date: Jun. 6, 2013

(54) Front Frame of Display and Display

(71) Applicant: Guofu Tang, Shenzhen (CN)

(72) Inventor: Guofu Tang, Shenzhen (CN)

(21) Appl. No.: 13/378,478

(22) PCT Filed: Dec. 6, 2011
(86) PCT No.: PCT/CN11/83582

§ 371 Date: Dec. 15, 2011

(30) Foreign Application Priority Data
Dec. 2, 2011 (CN) 2011103961806

(51) Int. Cl. H05K 7/14; F21V 17/00; G02F 1/1335

(52) U.S. Cl. 349/58; 361/679.01; 362/375

(57) ABSTRACT

The present invention discloses a front frame of a display and a display. The front frame of the display comprises a side plate which is positioned on the side surface of the display, and a transparent front cover, wherein the transparent front cover is fixedly connected with a side frame and is positioned on a light emergent surface of the display. In the present invention, the front frame with a transparent plate is adopted for fixing the display module of the display; similar to the existing display, the present invention preserves a wider frame; but because of the transparent characteristic of the front frame, an effective display area is not influenced; even if the front frame covers the whole display area, the display area is not influenced either; thus, the BM restriction is not considered; then, the restriction that a frame with a certain width must be required for original edge fixation is avoided and a super-narrow frame is achieved.

### TECHNICAL FIELD

The present invention relates to the field of displays, and more particularly to a front frame of a display and a display.

### BACKGROUND

A traditional display structure includes a display module 100 and a shell 200 used for fixing the module. The shell 200 includes a front frame used for fixing the display module 100, and a back shell 230; a system circuit board 220 can also be arranged between the back shell 230 and the display module 100 so that the display structure can be used as an integral machine. An extension part 111 of a middle frame 110 of the display module 100 encases a panel 120 for effectively fixing the panel 120; because a black matrix (BM) 121 of the panel 120 and the extension part 111 of the middle frame 110 are wide, the traditional display module cannot further reduce the length of the frame and the length of the extension part.

The front frame 210 of the shell 200 shall be joined on the extension part 111 of the front frame 110 of the display module for fixing the display module; thus, an edge part 211 of the front frame cannot be reduced. When the BM 121 of the panel 120 is narrower and narrower in design, the traditional structure cannot effectively locate the panel 120 so that a traditional display cannot further reduce the frame.

### SUMMARY

The aim of the present invention is to provide a front frame of a display and a display for achieving a super-narrow frame.

The aim of the present invention is achieved by the following technical schemes.

A front frame of a display. The front frame comprises a side plate which is positioned on the side surface of the display, and a transparent front cover, wherein the transparent front cover is fixedly connected with a side frame and is positioned on a light emergent surface of the display.

Preferably, the transparent front cover integrally covers a whole visible range. The front frame is not opened for the visible range and has an isolation function; thus, the panel can be completely sealed, the protection level is enhanced, and the possibility of the problem that a display screen is scraped, ruptured by impact and the like is reduced.

Preferably, the transparent front cover is provided with a hole on the visible range. The hole of the visible range can further increase transmittance and can also save the material cost of the front cover.

Preferably, the side plate is made of transparent material; the transparent front cover and the front cover are integrally formed. The production procedures can be simplified and the productivity can be increased by integrally forming the transparent front cover and the front cover with the same transparent material.

Preferably, paint is coated or an adhesive tape is pasted on the inner side wall of the side plate. This technical proposal can avoid light leakage and enhance optical utilization ratio.

Preferably, the side plate is made of opaque material; the front cover and the side plate are secondly formed or formed in double colors. By adopting secondary forming or bicolor forming, lightproof material can be adopted on the part of the side plate to achieve the purpose of avoiding light leakage of the side plate.

A display comprises the aforementioned front frame and a back cover which is fixedly connected with the front frame.

Preferably, the display sequentially comprises an optical component and an LCD panel in the direction from the back cover to the transparent front cover. Then, an LCD device is formed.

Preferably, a system circuit board is arranged between the back cover and the optical component. In the technical proposal, the LCD device can form systems with displays, such as televisions, integral machines and the like.

Preferably, the display is provided with an Organic Light-Emitting Diode (OLED) module between the back cover and the transparent front cover. Then, an OLED display is formed.

Preferably, the system circuit board is arranged between the back cover and the OLED module. In the technical proposal, the OLED device can form systems with displays, such as televisions, integral machines and the like.

Preferably, the side plate of the front frame is provided with a fixing device connected with the back cover of the display. This is a matching form of the front frame and the back cover.

Preferably, the fixing device is a fixing bolt. This is a concrete fixing device structure.

In the present invention, the front frame with a transparent plate is adopted for fixing the display module of the display; similar to the existing display, the present invention preserves a wider frame; but because of the transparent characteristic of the front frame, an effective display area is not influenced; even if the front frame covers the whole display area, the display area is not influenced either; thus, the BM restriction is not considered; then, the restriction that a frame with a certain width must be required for original edge fixation is avoided and a super-narrow frame is achieved.

### BRIEF DESCRIPTION OF FIGURES

FIG. 1 is a schematic diagram of the existing display module;

FIG. 2 is a schematic diagram of the existing display with a shell;

FIG. 3 is a schematic diagram of a whole structure in the example of the present invention;

FIG. 4 is a schematic diagram of a local structure in the example of the present invention;

FIG. 5 is a schematic diagram of a local structure in another example of the present invention;

FIG. 6 is a schematic diagram of assembly in the example of the present invention;

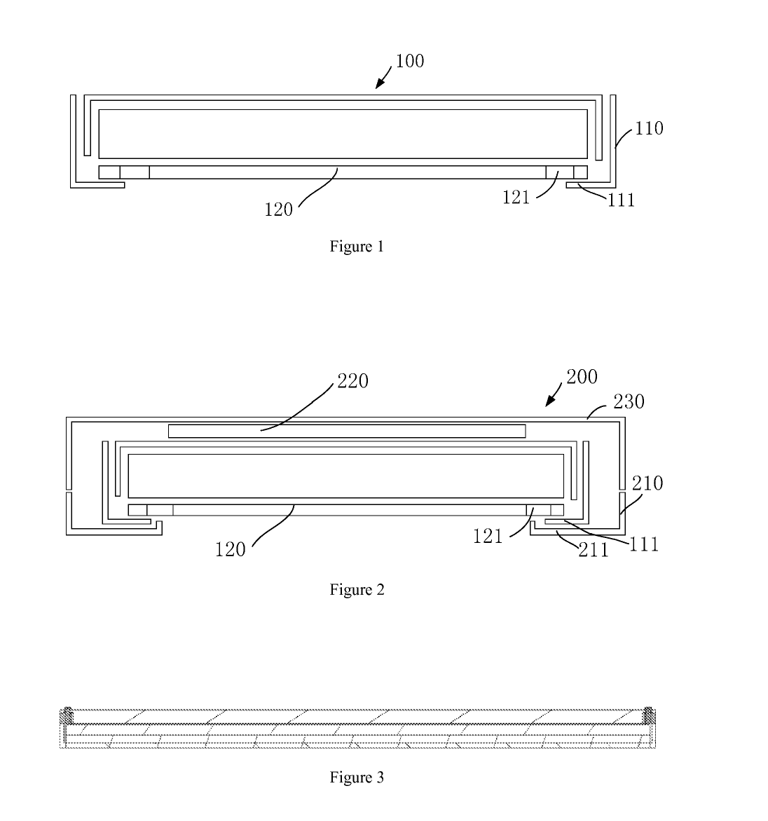

Wherein: 100. display module; 110. middle frame; 111. extension part; 120. panel; 121. BM; 200. shell; 210. front frame; 211. edge part; 310. transparent front cover; 320. LCD panel; 330. optical component; 340. back cover; 350. fixing bolt; 360. fastening screw.

### DETAILED DESCRIPTION

The present invention will be further described in accordance with the figures and the preferred examples.

A display comprises a front frame; the front frame comprises a side plate positioned on the side surface of the display, and a transparent front cover 310, wherein the transparent front frame 310 is fixedly connected with a side frame and is positioned on a light emergent surface of the display.

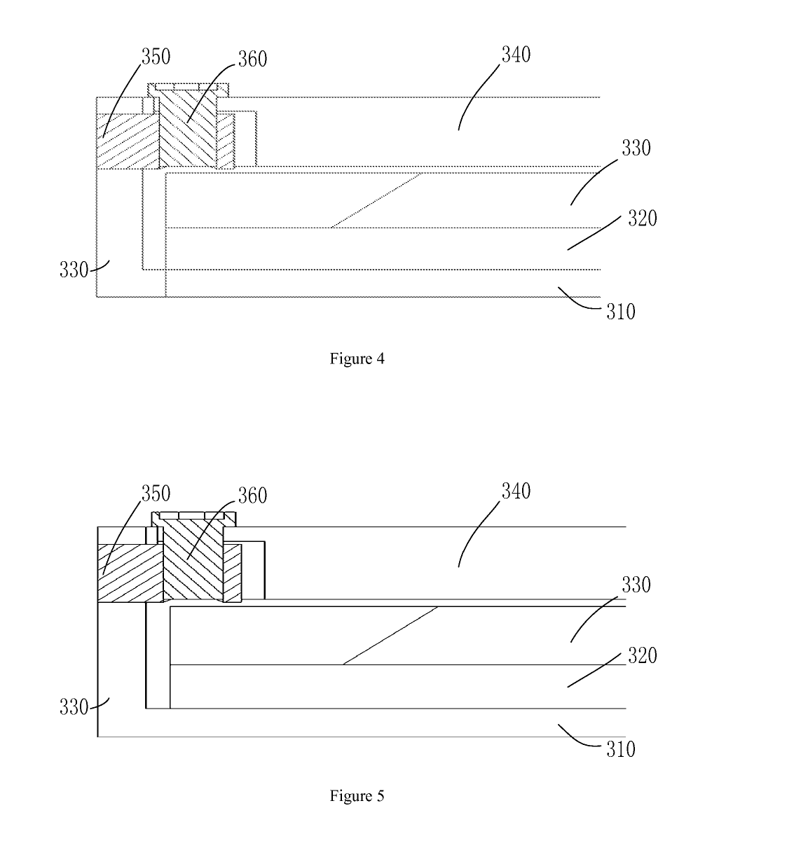

As shown in FIG. 4, the display is an LCD device; the LCD device comprises a front frame and a back cover 340; the front frame comprises a transparent front cover 310 and a side plate; one end of the side plate is fixedly connected with the transparent front cover 310, and the other end is provided with a fixing bolt 350; the back cover 340 is fixed with the side plate of the front frame through a fastening bolt 360; a liquid crystal is sequentially provided with an optical component 330 and an LCD panel 320 from the back cover to the transparent front cover 310.

After the back cover and the side plate of the front frame are fixed, a complete shell is formed; an LCD module which comprises an optical component 330 and an LCD panel 320 as shown in FIG. 4 can be put in the shell, or an OLED module without backlight is put in the shell; a system circuit board for controlling the display can also be further added between the back cover and the optical component 330 or the OLED module. The example can be used as the LCD module, or used for the OLED module without backlight, or used as an integral machine, namely the example can become a television as long as a system element (such as the system circuit board) and a base are added.

The side plate and the back cover 340 can be connected through the fixing bolt 350 or by the modes of pasting, bayonet coupling, riveting and the like. The technologies of the fixing bolt 350, such as thread fastening, pasting and the like, can be used for the fixing form of the fixing bolt 350 in the example; the fastening bolt 360 can be in the modes of thread fastening, clipping, pasting with glue and the like.

### EXAMPLE 1

As shown in FIG. 4, the front frame of the present invention is not opened for a visible range so as to positively contact and support the panel; the panel is directly supported by the transparent front cover 310; the optical component 330 is directly arranged on the panel; then, the fixing bolt 350 is assembled; after the back cover 340 is kept well, the back cover 340 is locked with the fastening bolt 360 so as to achieve the purpose of effectively fixing the panel and the optical component 330. Because the front frame is not opened for the visible range, the panel can be completely sealed, the protection level is enhanced, and the possibility of the problem that a display screen is scraped, ruptured by impact and the like is reduced. Certainly, the front frame can also be opened for the visible range so as to increase the transmittance and save the material cost of the front cover.

The side plate is made of transparent material; the production procedures can be simplified and the productivity can be increased by integrally forming the transparent front cover and the front cover.

As shown in FIG. 6, the assembly sequence of the example is described as follows: the transparent front cover 310 is put on a work table; the panel is put on the transparent front cover 310; then, the optical component 330 is put; a light bar and a heat sink are fastened in the relevant positions of the front cover of the transparent front cover 310; the fixing bolt 350 is locked on the side wall of the front cover of the transparent front cover 310; the back cover 340 in the relevant position of the fixing bolt 350 is slotted; the back cover 340 is positioned with the fixing bolt 350 by slotting; after the back cover 340 is buckled, the back cover 340 is fixed through the fastening bolt 360.

### EXAMPLE 2

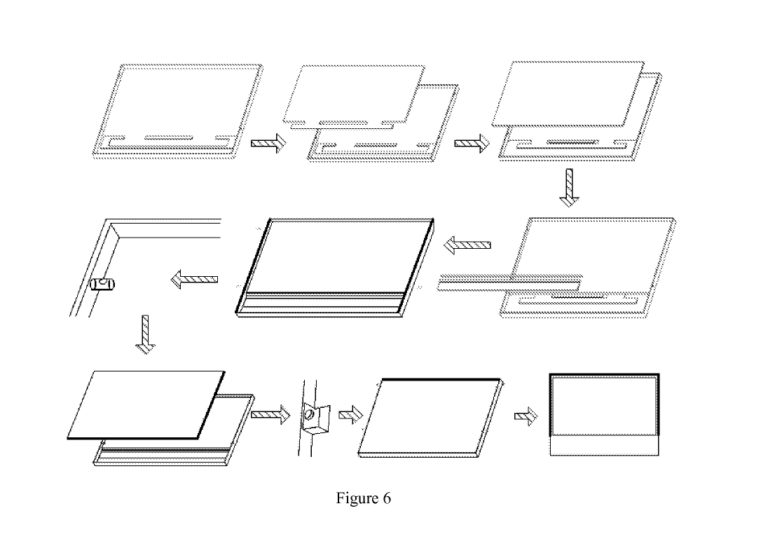

As shown in FIG. 5, the front frame of the present invention is not opened for a visible range so as to positively contact and support the panel; the panel is directly supported by the transparent front cover 310; the optical component 330 is directly arranged on the panel; then, the fixing bolt 350 is assembled; after the back cover 340 is kept well, the back cover 340 is locked with the fastening bolt 360 so as to achieve the purpose of effectively fixing the panel and the optical component 330. Because the front frame is not opened for the visible range, the panel can be completely sealed, the protection level is enhanced, and the possibility of the problem that a display screen is scraped, ruptured by impact and the like is reduced. Certainly, the front frame can also be opened for the visible range so as to increase the transmittance and save the material cost of the front cover.

To avoid light leakage of the side plate and enhance the optical utilization ratio, paint is coated or an adhesive tape is pasted on the inner side wall of the side plate; By adopting the mode of secondary forming or bicolor forming of the front cover and the side plate, lightproof material can be adopted on the part of the side plate to achieve the purpose of avoiding light leakage of the side plate.

As shown in FIG. 6, the assembly sequence of the example is described as follows: the transparent front cover 310 is put on a work table; the panel is put on the transparent front cover 310; then, the optical component 330 is put; a light bar and a heat sink are fastened in the relevant positions of the front cover of the transparent front cover 310; the fixing bolt 350 is locked on the side wall of the front cover of the transparent front cover 310; the back cover 340 in the relevant position of the fixing bolt 350 is slotted; the back cover 340 is positioned with the fixing bolt 350 by slotting; after the back cover 340 is buckled, the back cover 340 is fixed through the fastening bolt 360.

The present invention is described in detail in accordance with the above contents with the specific preferred examples. However, this invention is not limited to the specific examples. For the ordinary technical personnel of the technical field of the present invention, on the premise of keeping the conception of the present invention, the technical personnel can also make simple deductions or replacements, and all of which should be considered to belong to the protection scope of the present invention.

1. A front frame of a display; said front frame comprises a side plate which is positioned on the side surface of the display, and a transparent front cover, wherein the transparent front frame is fixedly connected with a side frame and is positioned on a light emergent surface of the display.

2. The front frame of the display of claim 1, wherein said transparent front cover integrally covers a whole visible range.

3. The front frame of the display of claim 1, wherein said transparent front cover is provided with a hole on the visible range.

4. The front frame of the display of claim 1, wherein said side plate is made of transparent material; said transparent front cover and said front cover are integrally formed.

5. The front frame of the display of claim 1, wherein paint is coated or an adhesive tape is pasted on the inner side wall of said side plate.

6. The front frame of the display of claim 1, wherein said side plate is made of opaque material; said front cover and said side plate are secondly formed or formed in double colors.

7. A display, comprising: the front frame of the display of claim 1, and a back cover fixedly connected with the front frame; said front frame comprises a side plate positioned on the side surface of the display, and a transparent front cover, wherein the transparent front cover is fixedly connected with a side frame and is positioned on a light emergent surface of the display.

8. The display of claim 7, wherein said display sequentially comprises an optical component and an LCD panel in the direction from said back cover to said transparent front cover.

9. The display of claim 8, wherein a system circuit board is arranged between said back cover and said optical component.

10. The display of claim 7, wherein said display is provided with an OLED module between said back cover and said transparent front cover.

11. The display of claim 10, wherein a system circuit board is arranged between said back cover and said OLED module.

12. The display of claim 7, wherein the side plate of said front frame is provided with a fixing device connected with the back cover of said display.

13. The display of claim 12, wherein said fixing device is a fixing bolt.

14. The display of claim 7, wherein said transparent front cover integrally covers a whole visible range.

15. The display of claim 7, wherein said transparent front cover is provided with a hole on the visible range.

16. The display of claim 7, wherein said side plate is made of transparent material; said transparent front cover and said front cover are integrally formed.

17. The display of claim 7, wherein paint is coated or an adhesive tape is pasted on the inner side wall of said side plate.

18. The display of claim 7, wherein said side plate is made of opaque material; said front cover and said side plate are secondly formed or formed in double colors.
